(19) United States
(12) Patent Application Publication
(10) Pub. No.: US 2005/0233530 A1
(43) Pub. Date: Oct. 20, 2005

(54) Enhanced gate structure

(76) Inventors: John P. Barnak, Beaverton, OR (US); Mark Doczy, Beaverton, OR (US); Robert S. Chau, Beaverton, OR (US); Collin J. Borla, Sherwood, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/154,747

(22) Filed: Jun. 15, 2005

Related U.S. Application Data
(62) Division of application No. 10/652,350, filed on Aug. 29, 2003.

(51) Int. Cl. H01L 21/8238; H01L 21/336; H01L 21/8234

(52) U.S. Cl. 438/287; 438/216; 438/591; 438/275

(57) ABSTRACT

A technique for producing an enhanced gate structure having a silicon-nitride buffer. Embodiments relate to the structure and development of a gate structure having a silicon-nitride buffer layer deposited upon a dielectric layer, upon which a gate material, such as polysilicon, is deposited.

### CROSS-REFERENCE TO RELATED APPLICATIONS

The present application is a divisional application of and claims the priority date of U.S. patent application Ser. No. 10/652,350 entitled “ENHANCED GATE STRUCTURE,” filed Aug. 29, 2003 and assigned to the assignee of the present invention.

### FIELD

Embodiments of the invention relate to semiconductor manufacturing. More particularly, embodiments of the invention relate to the formation of a silicon-nitride layer between a polysilicon gate structure and a dielectric within a complementary metal-oxide-semiconductor (CMOS) device.

### BACKGROUND

Typical CMOS devices have gate structures consisting of a dielectric layer deposited upon the device substrate and a polysilicon or metal gate structure deposited upon the dielectric layer. FIG. 1 illustrates a typical CMOS device having a prior art gate structure. Gate structures, such as those in FIG. 1, however, may experience adverse electrical effects or defects over time, including short circuits forming between the transistor gate material and the dielectric, pinning of the transistor gate material work function, and excessive defect densities between the transistor gate material and the dielectric. Pinning can occur when a defect within the polysilicon/gate oxide interface, and the work function of the gate electrode becomes approximately equal to the energy level or ban of energy levels of the defect.

Some of these adverse effects or defects may arise from adhesion problems between the dielectric layer and transistor gate material, such as doped polysilicon. Adhesion problems may arise due to high-temperature exposure of the gate structure during processing or cycling the gate voltage over time. As a result, the performance as well as the reliability of the transistor can be reduced.

### BRIEF DESCRIPTION OF THE DRAWINGS

Embodiments of the invention are illustrated by way of example and not limitation in the figures of the accompanying drawings, in which like references indicate similar elements and in which:

FIG. 1 is a typical transistor containing a prior art gate structure.

FIG. 2 is a CMOS device containing gate structures according to one embodiment of the invention.

FIG. 3 is a flow diagram illustrating a portion of a semiconductor process that may be used in conjunction with one embodiment of the invention.

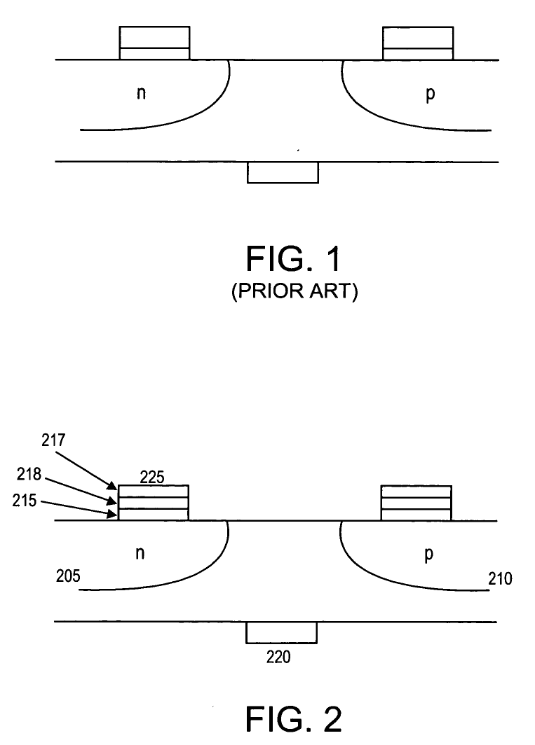

### DETAILED DESCRIPTION

Embodiments of the invention described herein relate to complementary metal-oxide-semiconductor (CMOS) processing. More particularly, embodiments of the invention relate to the creation of a gate structure in a transistor that is substantially resistant to defects, such as short circuits forming between the transistor gate material and the dielectric, pinning of the transistor gate material work function, and excessive defect densities between the transistor gate material and the dielectric.

FIG. 2 illustrates a CMOS device in which one embodiment of the invention may be used. The device of FIG. 2 is an inverter, which comprises an n-type transistor 205 and a p-type transistor 210. In each of the transistors is a dielectric layer 215, a polysilicon gate 218, and a buffer 217, across which an electric field is created when a gate voltage is applied to the gate 225 while the body 220 is biased at a lower potential than the gate. In the n-type transistor, the polysilicon gate is doped with n-type material, whereas in the p-type transistor, the polysilicon gate is doped with p-type material.

The buffer is a layer that may be formed upon the dielectric through various processing techniques, including physical vapor deposition (PVD). In one embodiment of the invention, the buffer contains silicon doped with nitrogen to form a silicon nitride layer between the polysilicon gate and the dielectric layer.

Advantageously, the silicon-nitride buffer reduces defect densities between the transistor polysilicon gate material and the dielectric layer. Furthermore, the buffer helps prevent electrical shorts from forming between the dielectric and the polysilicon gate while reducing pinning of the gate work function.

In the embodiment illustrated in FIG. 2, the dielectric layer has a substantially high dielectric constant in order to allow the dielectric layer to be as thin as possible while still being able to support the electric field produced by the voltage applied to the gate. For example, the dielectric layer of FIG. 2 has dielectric constant greater than twenty.

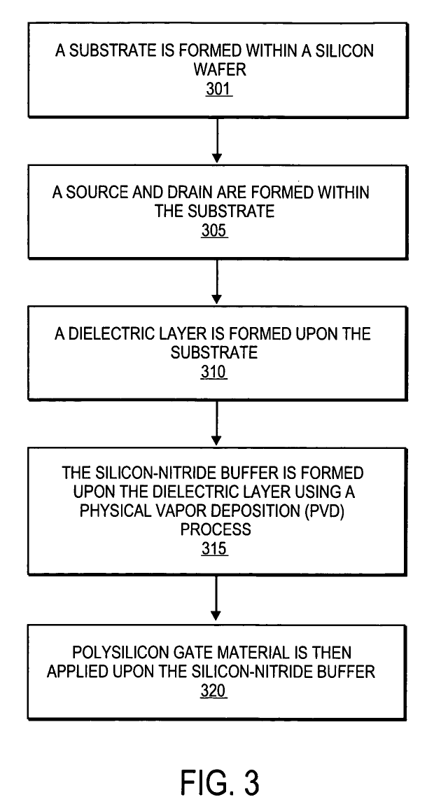

FIG. 3 is a flow diagram illustrating a number of operations in a semiconductor manufacturing process according to one embodiment. At operation 301, a substrate is formed within a silicon wafer. A source and drain are formed within the substrate at operation 305. A dielectric layer is formed upon the substrate at operation 310, and the silicon-nitride buffer is formed upon the dielectric layer using a physical vapor deposition (PVD) process at operation 315. Polysilicon gate material is then applied upon the silicon-nitride buffer at operation 320.

While the invention has been described with reference to illustrative embodiments, this description is not intended to be construed in a limiting sense. Various modifications of the illustrative embodiments, as well as other embodiments, which are apparent to persons skilled in the art to which the invention pertains are deemed to lie within the spirit and scope of the invention.

1. A method comprising:
forming a dielectric layer upon a semiconductor substrate;
forming a silicon-nitride layer upon the dielectric layer;
forming a polysilicon layer upon the silicon-nitride layer.

2. The method of claim 1 wherein the silicon-nitride layer is formed by depositing it upon the dielectric layer using a physical vapor deposition (PVD) process.

3. The method of claim 2 wherein the dielectric layer has a dielectric constant of twenty or greater.

4. The method of claim 3 wherein the polysilicon gate layer is n-type.

5. The method of claim 4 wherein the polysilicon gate layer is p-type.

6. The method of claim 2 wherein the dielectric layer, the silicon-nitride layer, and the polysilicon layer are part of a gate structure within a complementary metal-oxide-semiconductor device.

7. A process for forming a semiconductor device comprising:
forming a substrate;
forming a dielectric layer having a dielectric constant greater than twenty upon the substrate;
forming a polysilicon layer, the polysilicon layer being coupled to the dielectric layer by a buffer layer to help prevent electrical shorts between the polysilicon layer and the dielectric layer.

8. The process of claim 7 wherein the buffer layer is to help prevent pinning of the polysilicon layer's work function.

9. The process of claim 8 wherein the buffer layer is to help reduce defect density between the dielectric layer and the polysilicon layer.

10. The process of claim 7 wherein the buffer comprises silicon-nitride.

11. The process of claim 10 wherein the silicon nitride is deposited upon the dielectric layer using a physical vapor deposition (PVD) process.

12. The process of claim 11 wherein the polysilicon layer, the silicon-nitride layer, and the dielectric layer are part of a gate structure within a complementary metal-oxide-semiconductor (CMOS) device.

13. The process of claim 12 wherein the dielectric layer and the polysilicon layer are formed using CMOS process techniques.
